(19) United States
(12) Patent Application Publication
(10) Pub. No.: US 2015/0060776 A1
(43) Pub. Date: Mar. 5, 2015

(54) ORGANIC ELECTROLUMINESCENT DEVICE WITH ENERGY HARVESTING

(71) Applicants: Yi-Lu Chang, Toronto (CA); Zhibin Wang, Toronto (CA); Michael Helander, Toronto (CA); Jacky Qiu, Toronto (CA); Zhenghong Lu, Toronto (CA)

(72) Inventors: Yi-Lu Chang, Toronto (CA); Zhibin Wang, Toronto (CA); Michael Helander, Toronto (CA); Jacky Qiu, Toronto (CA); Zhenghong Lu, Toronto (CA)

(21) Appl. No.: 14/016,079

(22) Filed: Aug. 31, 2013

(51) Int. Cl. H01L 51/50; H01L 51/56

(52) U.S. Cl. CPC H01L 51/504; H01L 51/56
USPC 257/40; 438/46

(57) ABSTRACT

Provided herein is an organic light-emitting device and a method of construction thereof. The organic light-emitting device comprises an anode, a cathode, and at least two light-emitting layers located between the anode and the cathode. At least one of the light-emitting layers comprises a host compound having distributed therein a first compound capable of phosphorescent emission at room temperature and a second compound capable of phosphorescent emission at room temperature that has a peak emission wavelength at least 10 nm higher than the first compound.

### CROSS-REFERENCE TO RELATED APPLICATIONS

This application claims priority from U.S. Provisional Patent Application No. 61/695,562 filed on Aug. 31, 2012, the contents of which is hereby incorporated by reference in its entirety.

### TECHNICAL FIELD

The following relates generally to white organic light-emitting diodes.

### BACKGROUND

White organic light-emitting diodes (OLEDs) are considered a promising technology for next generation solid-state lighting and displays due to their many attributes such as high energy efficiency, eye-friendly diffusive warm light, ultra-thin form factor, etc.

In general, a white OLED consists of at least one organic layer disposed between an anode and a cathode that are electrically connected. Upon the application of a current, the cathode injects electrons and the anode injects holes into the organic layer(s). When a hole and an electron localize on the same organic molecule, an “exciton,” or a localized electron-hole pair with an excited energy state, is generated. Light is then emitted when the exciton relaxes to the ground state in a photoemissive mechanism. In order to produce a white emission, multiple dopants of different emitting colors or a single dopant with a broad-band emission (full-width-half-maximum of >120 nm) may be used to construct the light-emitting layer(s) inside an OLED.

To produce high efficiency white OLEDs, the use of phosphors has become indispensable, owing to theability of phosphors to generate light from both singlet and triplet excitons, thereby enabling OLEDs to achieve nearly 100% internal quantum efficiency.

In addition to high efficiency, a high color-rendering capability for objects viewed under such white illumination source is an important parameter for solid-state lighting. In particular, a color rendering index (CRI) of over 80 is required to qualify white OLEDs as suitable illumination sources. To increase CRI, hybrid WOLEDs employing a blue fluorophore along with green and red phosphors have been developed. For example Schwartz et al. has disclosed the use of such fluorophores in “Harvesting triplet excitons from fluorescent blue emitters in white organic light-emitting diodes”, Advanced Materials, 19, 3672 (2007). Such blue fluorophores typically exhibit more saturated blue emissions than typical blue phosphors. As a result, high CRI values of above 85 may be achieved but at a cost of lower device external quantum efficiency (EQE) of <20%.

To increase device efficiency, previous studies have explored using only two phosphorescent emitters to achieve high efficiencu, for example, Su et al. in “Highly efficient organic blue-and white-light-emitting devices having a carrier- and exciton-confining structure for reduced efficiency roll-off”, Advanced Materials, 20, 4189 (2008). Using this approach, an EQE of as high as 26% has been achieved; however, the device CRI values are typically lower than 70 due to a lack of emission wavelength coverage in the visible spectrum, diminishing the utility of these devices as illumination sources.

Additionally, other studies have reported white OLEDs having co-doped three or more phosphorescent emitters with different colors into one light-emitting layer while preserving all emission colors with the advantage of having a reduced total number of organic layers. One such example is demonstrated by D'Andrade et al. in “Efficient organic electrophosphorescent white light-emitting device with a triple doped emissive layer”, Advanced Materials, 16, 624 (2004). However, such an approach makes it more difficult to tune the emission spectrum as most of the energy will naturally transfer to the lower energy emitters. This typically results in the use of high concentration high energy dopants (e.g. blue phosphors) and low concentration low energy dopants (e.g. red phosphors) with respect to the host, which further limits the degree of control over the emission efficiency for each color, leading to a poor overall device efficiency (EQE <20%).

Very recently, Fleetham et al. have demonstrated white OLED devices with an EQE of 20.1% and a CRI of 80 using a single Pt-complex as the luminescent dopant in “Single-doped white organic light-emitting device with an external quantum efficiency of over 20%”, Advanced Materials, DOI: 10.1002/adma.201204602 (2013). However, the device external quantum efficiency quickly dropped to below 20% beyond a luminance of 1,000 cd/m², rendering the device impractical for lighting applications, where high efficiency at high brightness (1,000 cd/m²-5,000 cd/m²) is required. Although Pt-based phosphors may exhibit a broad-band emission spectrum, the efficiency is typically not up to par compared to Ir-based phosphors. Such low efficiency at high luminance is a general issue with single emitter white OLED devices.

Another white OLED device with an EQE of 21.5% and a CRI of 80.1 at 1,000 cd/m² using three separate light-emitting layers with Ir-based phosphors emitting in the primary colors was demonstrated by Sasabe et al. in “High-efficiency blue and white organic light-emitting devices incorporating a blue iridium carbine complex”, Advanced Materials, 22, 5003 (2010). However, beyond a luminance of 2,000 cd/m², the CRI dropped to below 80, making the device less practical for lighting applications. In general, such reduction in CRI arises due to a drop in efficiency of the inferior blue and red phosphors at high luminance compared to green phosphors.

Therefore, there remains a need for a white OLEDs has been able to achieve concurrently a high EQE of >20% and a high CRI of >80 in a wide luminance range of 100-5,000 cd/m² inclusive, including the high brightness portion of 1,000-5,000 cd/m² that is critical especially for solid-state lighting applications.

### SUMMARY OF THE INVENTION

In the present invention, OLED devices are constructed with at least two light-emitting layers, wherein at least one light-emitting layer comprises of an energy harvesting dopant and a luminescent dopant co-doped into a common host to achieve high efficiency and color quality at high brightness.

It is an object of the present invention to make OLED devices with a high EQE of >20% in a wide luminance range of 100-5,000 cd/m² inclusive, which includes the high brightness portion of 1,000-5,000 cd/m².

It is another object of the present invention to make OLED devices with a high color quality defined by a CRI of >80 in a wide luminance range of 100-5,000 cd/m² inclusive, which includes the high brightness portion of 1,000-5,000 cd/m².

It is yet another object of the present invention to make OLED devices with simultaneously a high color rendering index of 85 and an EQE of >20% at a high luminance of 5,000 cd/m².

In a first aspect, an organic electronic device is provided. The device comprises an anode, a cathode, at least two light-emitting layers located between the anode and the cathode, at least one light-emitting layer comprising:
a host compound comprising:
   a first compound capable of phosphorescent emission at room temperature; and
   a second compound capable of phosphorescent emission at room temperature that has a peak emission wavelength at least 10 nm higher than the first compound.

In a second aspect, there is provided a method of constructing an organic electronic device. The method comprises an anode, a cathode, at least two light-emitting layers located between the anode and the cathode, and at least one light-emitting layer comprising:

Sandwiching between the anode and cathode a first light emitting layer and a second light emitting layer, the second light emitting layer comprising a host compound having distributed therein:
a first compound capable of phosphorescent emission at room temperature; and
a second compound capable of phosphorescent emission at room temperature that has a peak emission wavelength at least 10 nm higher than the first compound.

### DISCLOSURE OF THE INVENTION

An embodiment of the invention will now be described by way of example only with reference to the accompanying drawings.

### BRIEF DESCRIPTION OF THE DRAWINGS

FIG. 1 is an example OLED device.

FIG. 2 is an inverted OLED device that does not have electron and hole blocking layers or any spacers between adjacent light-emitting layers.

FIG. 3 is the possible types of light-emitting layer in an OLED device, where the present invention introduces an energy harvesting dopant (EHD1) together with a standard luminescent dopant (LD1) into a common host material.

FIG. 4A is an example device configuration of four example white OLEDs, W1 through W4.

FIG. 4B is an example energy level diagrams for white OLEDs W1-W4.

FIG. 5 is a plot of the spectral power spectra of the layers of device W1 of FIG. 4A at 10 mA/cm² as each emissive layer is progressively added to construct device W1.

FIG. 6 is a plot showing the relationship between luminance and efficiency of device W1 of FIG. 4A.

FIG. 7 is a plot showing the relationship between output emitted wavelength and normalized electroluminescent intensity of device W1 of FIG. 4A.

FIG. 8 is a plot showing the relationship between luminance and efficiency of device W2 of FIG. 4A.

FIG. 9 is a plot showing the relationship between output emitted wavelength and normalized electroluminescent intensity of device W2 of FIG. 4A

FIG. 10 is a plot showing the relationship between luminance and efficiency of device W3 of FIG. 4A.

FIG. 11 is a plot showing the relationship between output emitted wavelength and normalized electroluminescent intensity of device W3 of FIG. 4A.

FIG. 12 is a plot showing the relationship between luminance and efficiency of device W4 of FIG. 4A.

FIG. 13 is a plot showing the relationship between output emitted wavelength and normalized electroluminescent intensity of device W4 of FIG. 4A.

FIG. 14A is a plot showing the relationship between luminance and efficiency of device W4 of FIG. 4A with and without lens-based out-coupling enhancement.

FIG. 14B is the normalized electroluminescent intensity spectra of device W4 of FIG. 4A under various luminance levels with lens-based out-coupling enhancement.

FIG. 15 is a plot of spectral power plot of co-doped and single-doped red emitting devices at 10 mA/cm².

FIG. 16 is an enlarged view of the portion of the spectrum enclosed by the dashed box in FIG. 15.

FIG. 17 is a plot of spectral power plot of co-doped and single-doped yellow emitting devices at 10 mA/cm².

FIG. 18 is an enlarged view of the portion of the spectrum enclosed by the dashed box in FIG. 17.

FIG. 19 is a plot of the photoluminescence emission spectra of Ir(ppy)₂(acac) and the absorption spectra of Ir(BT)₂(acac) and Ir(MDQ)₂(acac) in CH₂Cl₂(˜1×10⁻⁵ M).

FIG. 20 is a diagram of an example single-color device structure used to determine the fraction of emissive excitons utilized by each emitter in the device.

FIG. 21 is a plot of current density versus voltage of devices W1 through W4 the four white OLED devices.

FIG. 22A is a plot of the solid state transient response of red and green co-doped CBP films at various co-doping concentrations. The dashed lines are the exponential fits to the transient decay responses. The excitation wavelength is at 350 nm.

FIG. 22B is a plot of the solid state transient response of yellow and green co-doped CBP films at various co-doping concentrations.

FIG. 22C is a plot of the calculated energy transfer rate and efficiency versus total dopant concentration with the control sample concentration corresponding to the green donor concentration of the co-doped films of FIGS. 22A and 22B.

FIG. 23 is an illustration of direct and indirect (through exciton diffusion) energy transfer processes involved between donor green molecules and acceptor yellow or red molecules. Dashed circles represent donor molecules and solid circles represent acceptor molecules.

FIG. 24 is a summary of white OLED performances of devices W1 through W4 of FIG. 4A.

FIG. 25 is a list of parameters used for obtaining the fraction of emissive excitons utilized by the dopants in optimized one-color OLED deviceswherein ηₑₓₜ is recorded at a luminance of 1,000 cd/m².

### DETAILED DESCRIPTION

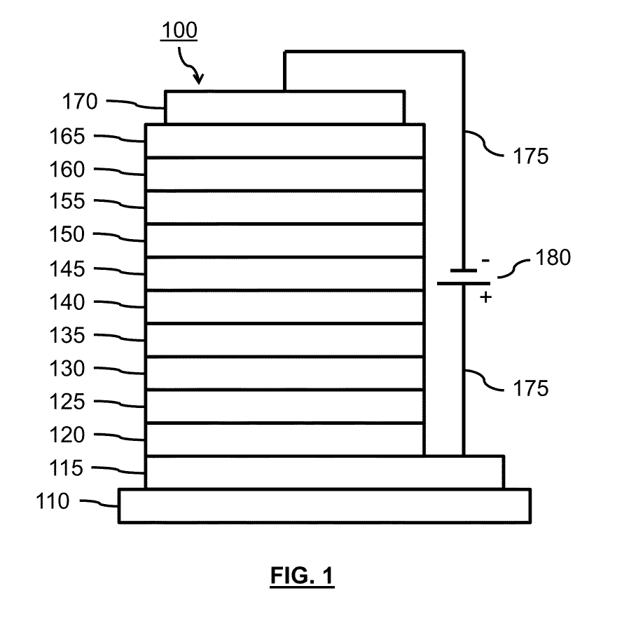

FIG. 1 shows a white OLED device 100. The figures depicting device structures are not drawn to scale. Device 100 may include a substrate 110, an anode 115, a hole injection layer 120, a hole transport layer 125, an electron blocking layer 130, a light-emitting layer 135, a spacer 140, a second light-emitting layer 145, another spacer 150, a third light-emitting layer 155, a hole blocking layer 160, an electron injection layer 165, and a cathode 170. The entire stack is connected electrically from the anode and the cathode through an electrical wire 175 that is connected to a voltage/current source 180. Device 100 may be fabricated, for example, by depositing the layers described, in order. The functions and properties of these various layers, in addition to example materials, are described in more detail in U.S. Pat. No. 7,279,704 at cols. 6-10, which are incorporated by reference.

Additional examples for each of these layers are available. For instance, a transparent and flexible substrate-anode combination is disclosed in U.S. Pat. No. 5,844,363, which is incorporated by reference in its entirety. An example of a p-doped hole transport layer is disclosed in U.S Patent Application Publication No. 2003/0230980, which is incorporated by reference in its entirety. An example of an n-doped electron transport layer is disclosed in U.S. Patent Application Publication No. 2003/0230980, which is incorporated by reference in its entirety. Examples of cathodes are disclosed in U.S. Pat. Nos. 5,703,436 and 5,707,745, which are incorporated by reference in their entireties. The theory and use of electron and hole blocking layers are described in detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety.

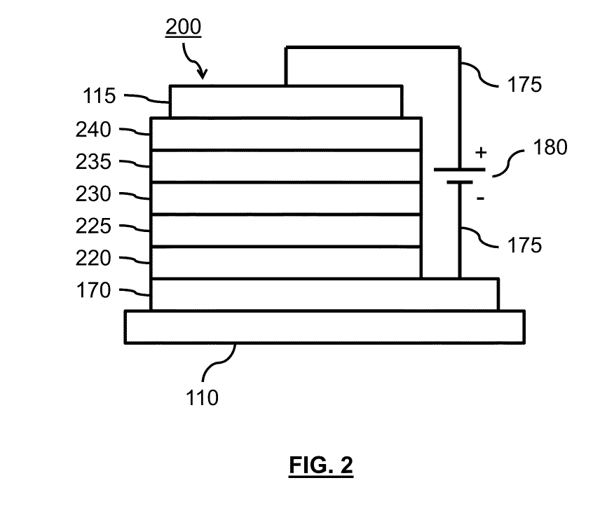

FIG. 2 shows an inverted white OLED 200. The device includes a substrate 110, a cathode 170, an electron transport layer 220, a light-emitting layer 225, another light-emitting layer 230, a hole transport layer 235, a hole injection layer 240, and an anode 115. The device is electrically connected from the anode and the cathode through an electrical wire 175 that is connected to a voltage/current source 180. Device 200 may be fabricated by depositing the layers described, in order. Since common white OLED configuration has a cathode disposed over the anode whereas device 200 has cathode 170 disposed under the anode 115, device 200 may be referred to as an “inverted” white OLED. Materials used in device 100 may be applied in a similar manner in device 200. FIG. 2 further provides one example of how several layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used.

Even though many of the examples provided here describe various layers as comprising a single material, it is understood that combination of materials, such as a mixture of host and dopant, or more generally a mixture, may be used. The names given to the various layers here are not intended to be strictly limiting. For example, in device 200, electron transport layer 220 transports electrons and injects electrons into the light-emitting layers, and may be described as an electron transport layer or an electron injection layer. In one embodiment, a white OLED may be described as having an “organic layer” disposed between a cathode and an anode. This organic layer may be consisted of a single layer, or may further be consisted of multiple layers of different organic materials as described, for instance, with respect to FIGS. 1 and 2.

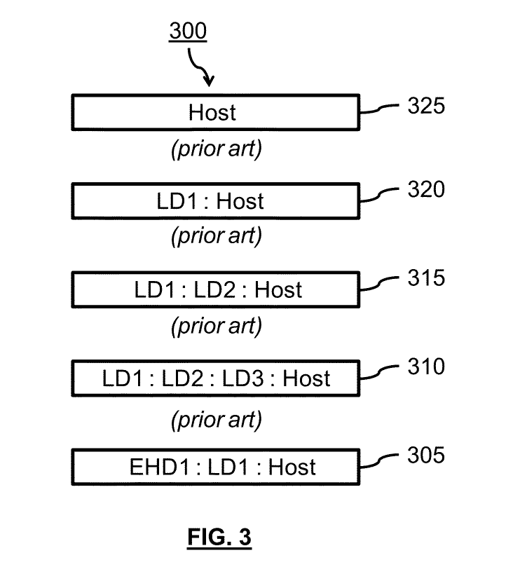

FIG. 3 shows various example configurations that make up a light-emitting layer 300 in a white OLED. Specifically, a light-emitting layer may be consisted of a single emissive host 325, a single luminescent dopant doped into a common host 320, two luminescent dopants doped into a common host 315, or three luminescent dopants doped into a common host 310, which are listed as prior art. An example of a light-emitting layer comprised of an emissive host is demonstrated by Tang et al. in “Organic electroluminescent diodes”, Applied Physics Letters, 51, 913 (1987). An example of a light-emitting layer comprised of one luminescent dopant doped into a host layer is demonstrated by Reineke et al. in “White organic light-emitting diodes with fluorescent tube efficiency”, Nature, 459, 234 (2009), wherein one luminescent dopant for each primary color is doped into a host material as separate light-emitting layers. An example of two luminescent dopants doped into a common host to construct the light-emitting layer is disclosed in U.S. Patent Application Publication No. 2010/0244725 to Adamovich et al., which is incorporated by reference in its entirety. An example of three luminescent dopants doped into a common host to construct the light-emitting layer is demonstrated by D'Andrade at el. in “Efficient organic electrophosphorescent white-light-emitting device with a triple doped emissive layer”, Advanced Materials, 16, 624 (2004).

The luminescent dopant(s) described herein may be phosphorescent or fluorescent. An example of a fluorescent dopant used in the light-emitting layer is demonstrated by Sun et al. in “Management of singlet and triplet excitons for efficient white organic light-emitting devices”, Nature 440, 908 (2006). The host described herein may also include a mixture of two or more materials as demonstrated by Lee at el. in “Enhanced efficiency and reduced roll-off in blue and white phosphorescent organic light-emitting diodes with a mixed host structure”, Applied Physics Letters, 94, 193305 (2009). In addition, the luminescent dopant(s) may also be doped into an emissive host as demonstrated by Chen et al. in “Ultra-simple hybrid white organic light-emitting diodes with high efficiency and CRI trade-off: Fabrication and emission-mechanism analysis”, Organic Electronics, 13, 2807 (2012). More examples of emissive dopant and host materials are disclosed in U.S. Pat. No. 6,303,238 to Thompson et al., which is incorporated by reference in its entirety.

Provided herein, is an energy harvesting dopant (EHD1) is doped along with a luminescent dopant (LD1) into a common host layer 305 shown in FIG. 3 for white OLED devices. A function of the energy harvesting dopant is to enhance the emission intensity, efficiency of the luminescent dopant at high brightness, or both, thereby tuning the overall device white emission spectrum. The energy harvesting dopant and the luminescent dopant may be a fluorescent or phosphorescent molecule. The peak emission wavelength of the luminescent dopant is at least 10 nm larger than the peak emission wavelength of the energy harvesting dopant to ensure effective energy transfer from the energy harvesting dopant to the luminescent dopant.

Structures and materials other than those specifically listed in the examples below may also be used. Examples include OLEDs comprised of polymeric materials (PLEDs) such as disclosed in U.S. Pat. No. 5,247,190 to Friend et al., which is incorporated by reference in its entirety. Additionally, OLEDs may be stacked, for example as described in U.S. Pat. No. 5,707,745 to Forrest et al., which is incorporated by reference in its entirety. The OLED structure may also deviate from the simple layered structure illustrated in FIGS. 1 and 2. For example, the substrate may contain an angled reflective surface to improve out-coupling, such as a mesa structure as described in U.S. Pat. No. 6,091,195 to Forrest et al., which is incorporated by reference in its entirety.

Any of the layers of the various embodiments may be deposited by any suitable method. For the organic layers, preferred methods include thermal evaporation, ink-jet printing, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. patent application Ser. No. 10/233,470, which is incorporated by reference in its entirety.

Other suitable deposition methods include spin-coating and other solution based processes, which are preferably carried out in nitrogen or an inert atmosphere. For the other layers, preferred methods include thermal evaporation, e-beam evaporation and sputtering. Preferred patterning methods include deposition through a mask. Materials with asymmetric structures may have better solution processibility than those having symmetric structures, because symmetric materials have a higher tendency to recrystallize.

Device fabricated in accordance with embodiments of the invention may be incorporated into a variety of consumer products, such as portable mobile displays, flat panel displays, computer/laptop monitors, television displays, billboards, lighting for interior or exterior illumination and/or signalling, heads-up displays, transparent displays, flexible displays, laser printers, digital cameras, micro-displays, automobile head-lights/displays, large area wall displays, theater screen displays or stadium screen displays. A variety of control mechanisms may be used to control devices fabricated in accordance with the present invention, including passive matrix and active matrix systems.

The materials and structures described herein may have applications in devices other than OLEDs. For example, other optoelectronic devices such as organic solar cells, organic photodetectors, organic transistors and organic light-emitting transistors (OLETs) may employ the materials and structures presented.

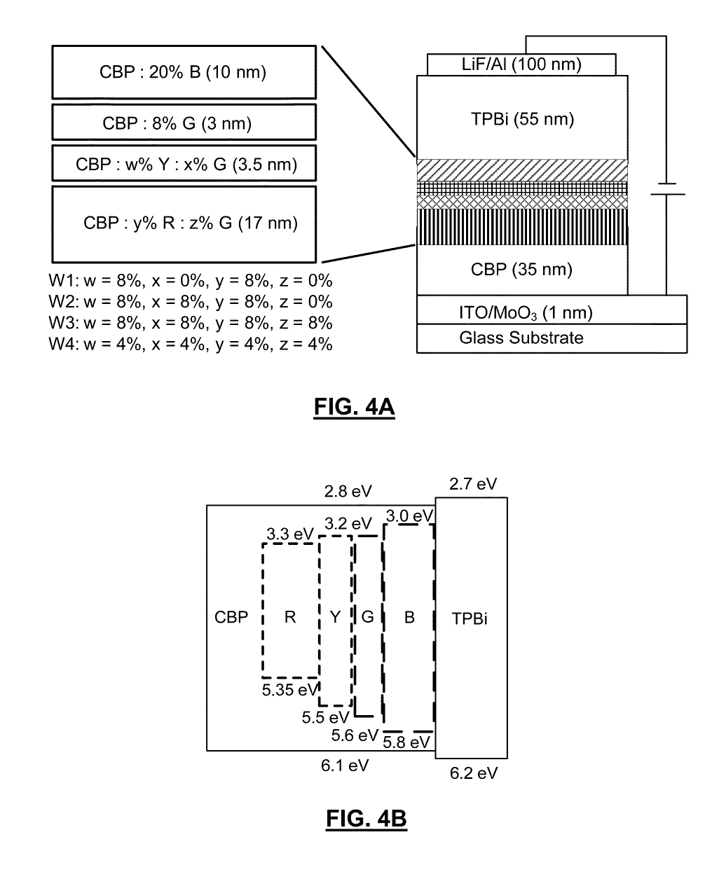

FIG. 4A is a schematic illustration of four example white OLED device structures (W1-W4), and FIG. 4B shows a representation of the corresponding energy level diagram. In each of devices W1 through W4, TPBi [2,2′,2″-(1,3,5-benzinetriyl)-tris(1-phenyl-1-H-benzimidazole)] serves as the electron transport layer (ETL), and CBP [4,4′-bis(carbazol-9-yl)biphenyl] functions as a hole transport layer (HTL), and as a triplet host. ITO/MoO₃ anode and LiF/AI cathode are applied. In this configuration, the majority of excitons will be generated near the CBP/TPBi interface (on both sides) before being harvested by the emitters (i.e. recombination occurs) on the CBP side.

As both CBP and TPBi are wide energy gap materials with high triplet energies, the generated excitons can be well-confined onto the emitters. Since the blue emitter, Flrpic, has the closest energy levels to both materials, direct exciton formation on the blue dopant is unlikely and it is critical to place the blue emitter closest to the CBP/TPBi interface to harvest excitons first. Other lower energy green, yellow and red emitters are placed sequentially next to blue to harvest excitons in a cascaded fashion as shown by the energy level diagram in FIG. 4B.

This cascaded design using a single host allows for only a single site for exciton generation and recombination without introducing other barrier layers (i.e. a second or third host material) that could induce undesirable charge accumulation in the device, leading to notorious triplet-polaron and polaron-polaron quenching processes.

In this example there is no interlayer or spacer between two adjacent emitting layers so that the surplus excitons can readily diffuse into the adjacent layer with an emitter having a lower energy. This inter-zone free flow of excitons is in stark contrast to the widely accepted design involving the use of interlayers, and can enhance device overall quantum efficiency.

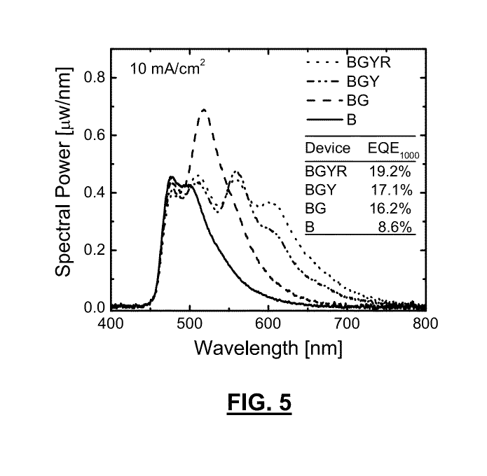

To demonstrate this point, a series of devices with one emitter (blue), two emitters (blue and green), three emitters (blue, green, and yellow), and four emitters (blue, green, yellow, and red) have been fabricated as shown in FIG. 5. It is found that with each additional emitter incorporated, the EQE progressively improves from 8.5% to 19.2% as the emissive zone increases from one to four, respectively.

It is observed that for blue doped only device, the emission efficiency is relatively low (<10%), indicating that a considerable portion of the excitons are not being transferred from CBP to Flrpic. However, with the inclusion of a green doped region adjacent to the blue doped region, the device shows a nearly twofold increase in efficiency without sacrificing the emission from Flrpic, which demonstrates that the energy transfer from CBP to Flrpic, and then to the adjacent Ir(ppy)₂(acac) is less significant compared to direct CBP energy transfer to the Ir(ppy)₂(acac) after exciton diffusion in host CBP from blue to green doped region. This shows that excitons generated near the CBP/TPBi interface are effectively harvested by the cascaded emission zones.

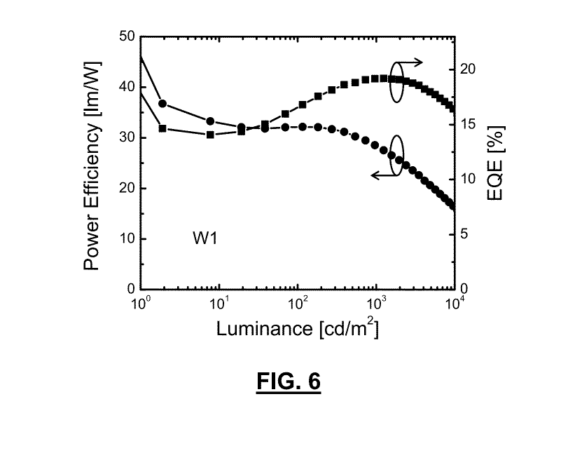

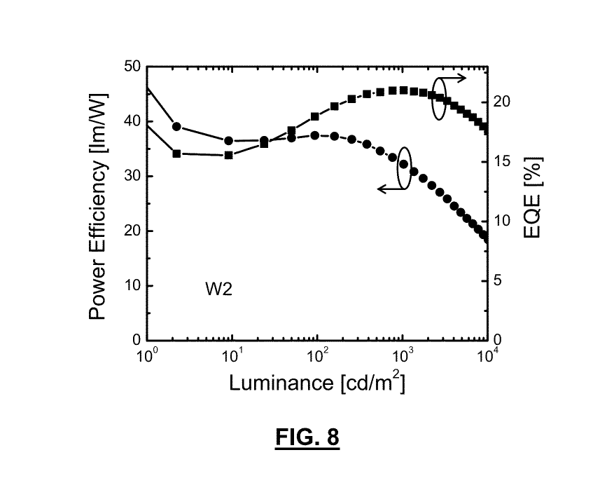

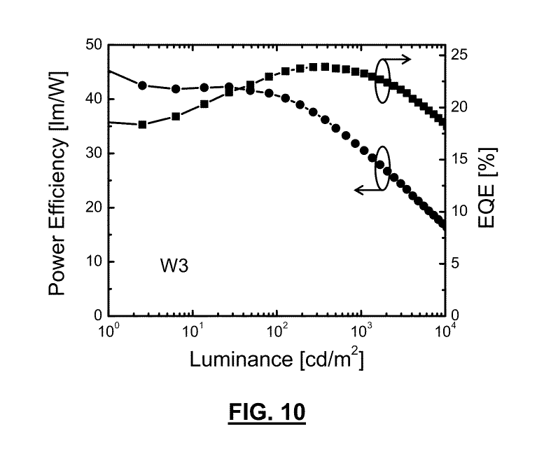

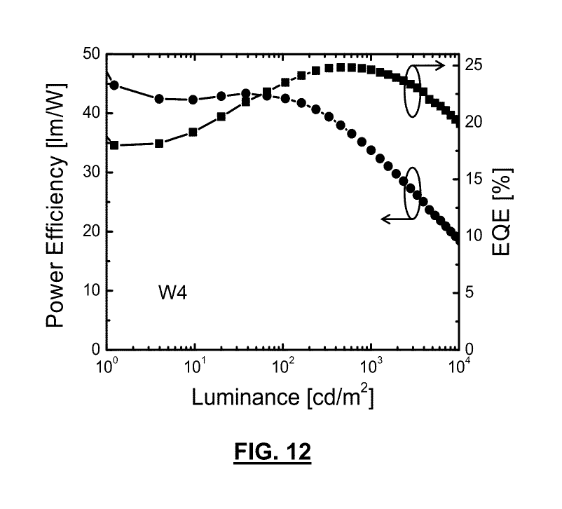

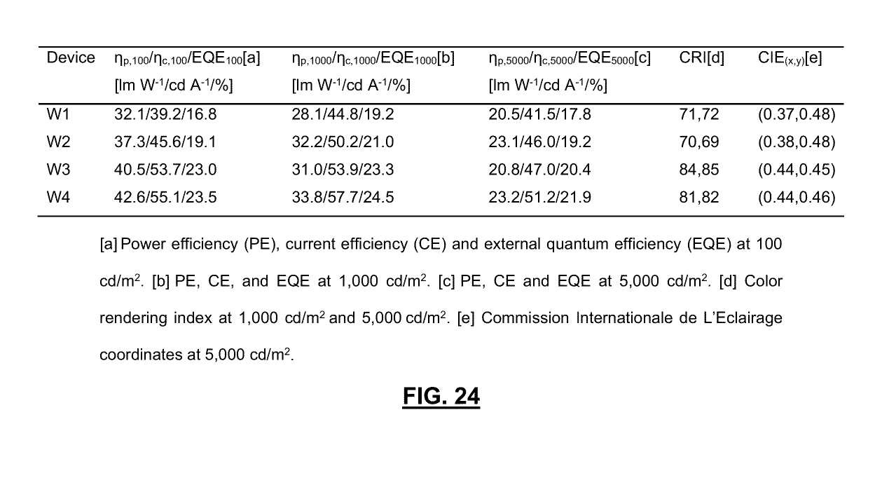

A summary of device performance is listed in FIG. 24, and the power efficiency-luminance-external quantum efficiency (PE-L-EQE) characteristics as well as the corresponding electroluminance (EL) spectrum (insets) of each device are shown in FIG. 6 to FIG. 13. The inter-zone exciton harvesting concept led to device W1 with decent EQE₁₀₀ (η_{p,100}) and EQE₁₀₀₀ (η_{p,1000}) of 16.8% (32.1 lm/W) and 19.2% (28.1 lm/W), respectively. The high efficiency at high luminance is mainly due to the elimination of accumulated carriers across the entire device, i.e. the unique design of using CBP as both the host and hole transport layer, which has been demonstrated.

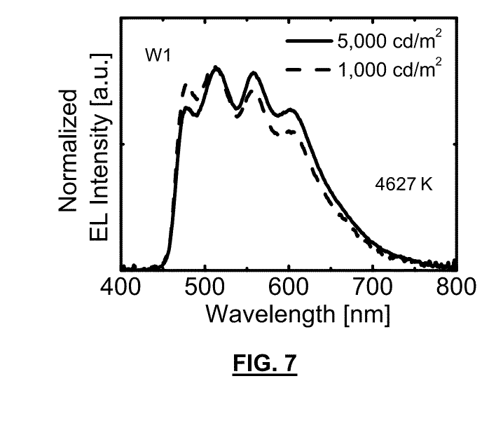

Also noted is the spectral shift with a reduction in blue emission and improvement in yellow and red emissions at higher luminance as shown in FIG. 7. This may be attributed to a shift of the exciton generation towards the yellow and red doped regions at higher driving voltages. Since CBP is also an electron transporter, at a higher driving voltage, relatively more electrons can be injected deeper into the CBP side to form excitons in the host which are subsequently transferred to the yellow and red dopants, resulting in the emission intensity enhancement.

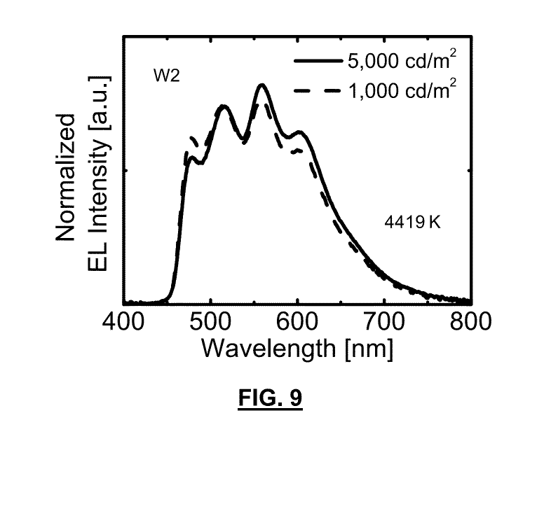

In order to enhance the efficiency of the device, a higher energy (green) phosphor is incorporated into the yellow emissive layer (W2) to enable intra-zone TEC, i.e. molecular energy transfer within a common emissive layer. From previous study on single color red OLED devices, it is known that incorporation of the green phosphor will improve the emission efficiency of a red OLED, while preserving the overall emission spectrum, i.e. the EL spectrum remains predominantly in red. Similarly, with the green phosphor incorporation in device W2, the yellow emission is enhanced, becoming the dominant emission peak as shown in FIG. 9. This spectral intensity enhancement corresponds to a improvement in EQE₁₀₀ and EQE₁₀₀₀ to 19.1% (37.3 lm/W) and 21.0% (32.2 lm/W), respectively. However, devices W1 and W2 exhibit CRI values of only 71 and 70 (see FIG. 24), respectively, which do not qualify them as adequate illumination sources.

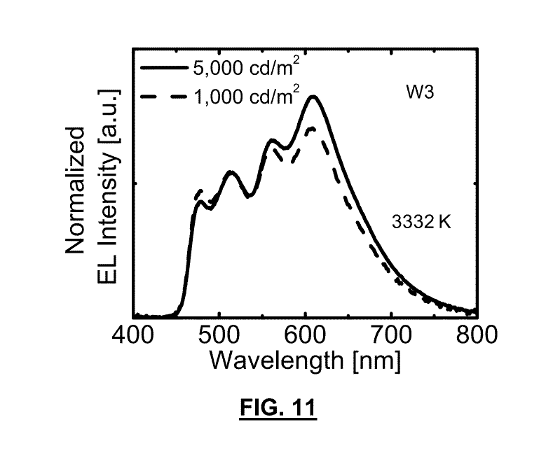

To improve the CRI, a green phosphor is further incorporated into the red emissive layer in addition to the yellow emissive layer (W3). From the EL spectrum in FIG. 11, it is observed that the red emission at ˜610 nm becomes the most dominant peak, leading to a high CRI of 84 at 1,000 cd/m². The green phosphor incorporation in the red emissive region also enhanced EQE₁₀₀ and EQE₁₀₀₀ to 23.0% (40.5 lm/W) and 23.3% (31.0 lm/W), respectively. At a high luminance of 5,000 cd/m² that is critical for solid-state lighting, the EQE remains as high as 20.4% with a high CRI of 85, Commission Internationale de L′Eclairage (CIE) coordinates of (0.44, 0.45) and a correlated color temperature (CCT) of 3332 K, corresponding to a desirable warm white illumination.

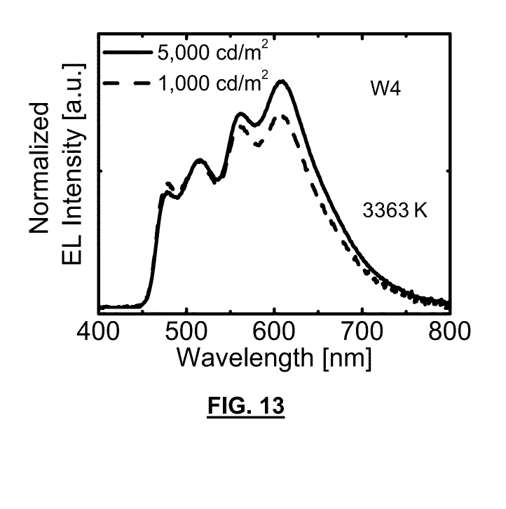

To further relieve the triplet-triplet annihilation and triplet-polaron quenching processes at high luminance, the co-doping concentrations in both yellow and red emissive regions are lowered as demonstrated in W4. It is observed in FIG. 13 that the spectrum is characterized by a slightly increased yellow emission compared to W3. Notably, the EQE₁₀₀, EQE₁₀₀₀ and EQE₅₀₀₀ have improved to 23.5% (42.6 lm/W), 24.5% (33.8 lm/W), and 21.9% (23.2 lm/W), respectively. Even at an ultra-high luminance of 10,000 cd/m², the EQE remains as high as 20.1% with a CRI of 82.

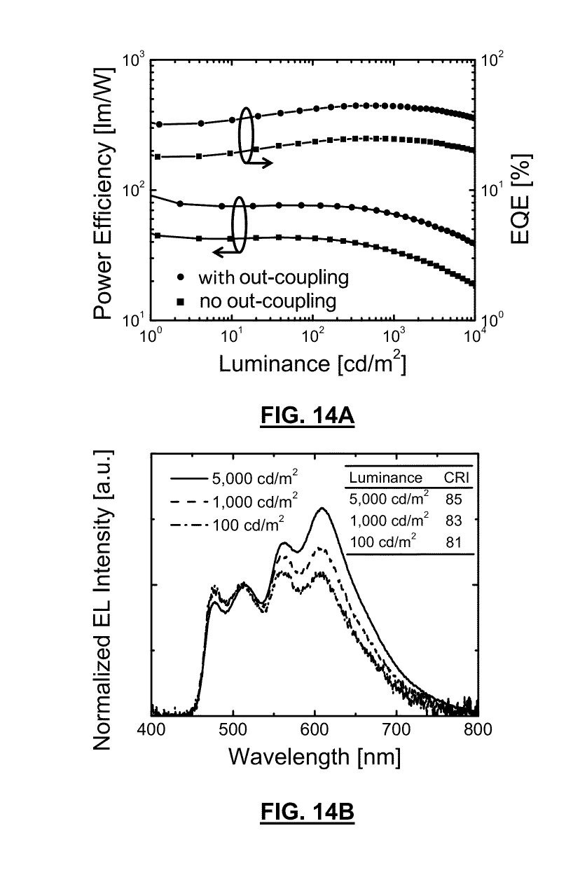

To reduce the loss in optical out-coupling, a simple lens-based out-coupling enhancement technique is used to obtain η_{p,100} (EQE₁₀₀), η_{p,1000} (EQE₁₀₀₀) and η_{p,5000} (EQE₅₀₀₀) of 76.0 lm/W (41.5%), 61.7 lm/W (44.3%) and 42.9 lm/W (40.6%), respectively, for W4, as shown in FIG. 14A. The corresponding CRI values are 81, 83 and 85, respectively as shown in FIG. 14B. All spectra are normalized to the green emission peak at ˜520 nm.

The resulting efficiency enhancement factor is approximately 1.8. These power efficiencies are in the range of standard fluorescent tubes (40-70 lm/W), however, the color rendering index is superior for lighting applications.

To investigate the working principle behind the performance improvement in these WOLEDs, the device structure is simplified by investigating the performance enhancement on one-color yellow and one-color red OLED devices while maintaining the same EML and transport layer thickness as in the white OLED devices.

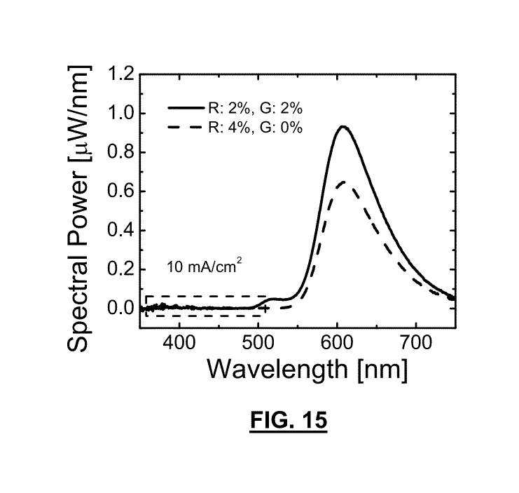

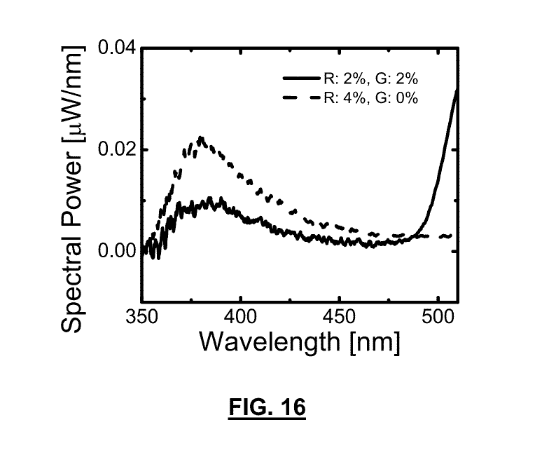

FIG. 15 illustrates the spectral power, i.e. the total radiant power per wavelength, of the red device with and without green phosphor incorporation in the emissive layer. It is apparent that both spectra are characterized by a dominant red peak at ˜605 nm, but the device with green phosphor incorporation shows a higher spectral power with an additional small peak attributed to the green phosphor emission (520 nm). More importantly, by examining closely at the spectra (FIG. 16), a higher host CBP emission from solely red doped device is observed, indicating that the green phosphor can assist in trapping excitons or utilizing excitons formed in the CBP host more efficiently.

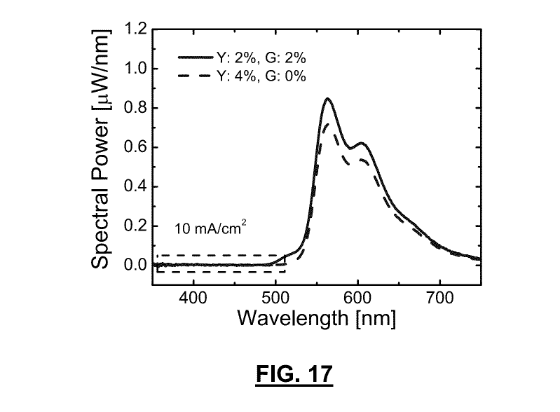

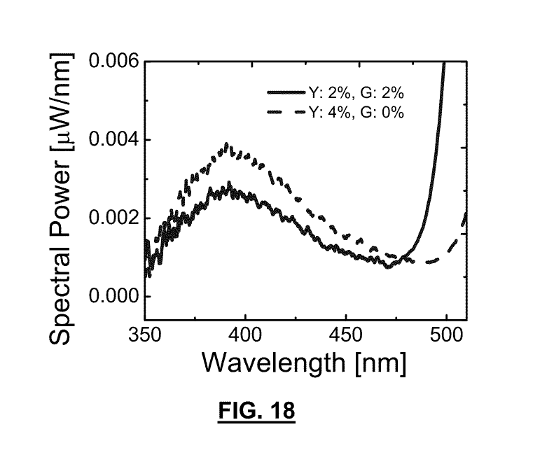

The above phenomenon is also observed for yellow emission devices as shown in FIGS. 17 and 18.

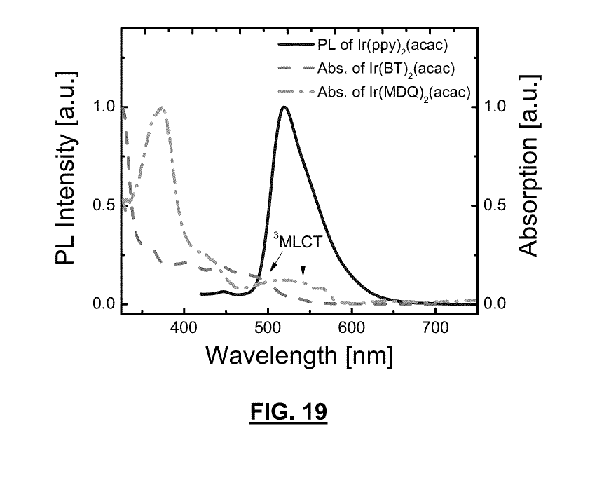

FIG. 19 illustrates the photoluminance (PL) spectrum of the green phosphor and the absorption spectra of yellow and red phosphors in solution. There is a substantial spectral overlap between the green phosphor triplet emission and the triplet metal-ligand-charge-transfer (³MLCT) states absorption of both red and yellow phosphors, which may enablethe efficient energy transfer cascade when the green phosphor is included in the device. This cascaded energy transfer appears to be relatively long range, given the levels of phosphor doping in these devices. That suggests a Förster-type mechanism is involved, which may be promoted by spin-orbit coupling or allowed by angular momentum conservation.

It can therefore be deduced that the efficiency enhancement is attributed to improved host exciton utilization by the green phosphor, followed by efficient triplet energy transfer from the green to lower energy yellow or red emitters as expressed by:

ηₑₓₜ=γηₒᵤₜχφ_{PL} (1a)

=γηₒᵤₜ{χ_{A}φ_{PL,A}+χ_{D}[η_{D-A}φ_{PL,A}+(1−η_{D-A})φ_{PL,D}]} (1b)

where ηₑₓₜ is the external quantum efficiency, γ represents charge balance factor, gout is the out-coupling efficiency, [symbol] denotes the fraction of emissive excitons that are trapped by the donor ( [symbol] _{D}) and acceptor molecules ( [symbol] _{A}), φ_{PL} is the quantum yields of the emitters, and η_{D-A} stands for the energy transfer efficiency from donor (D) to acceptor (A), i.e., from green to yellow or red phosphors.

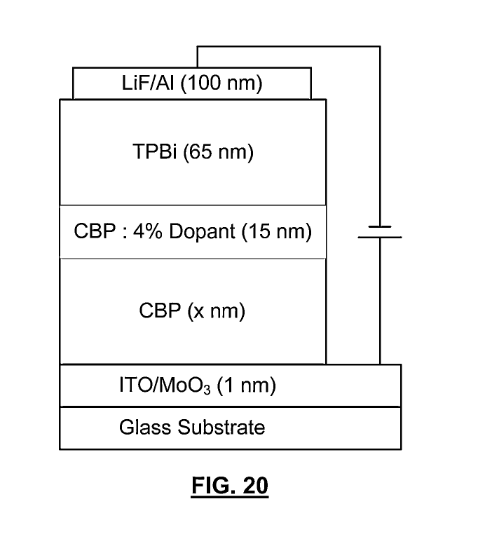

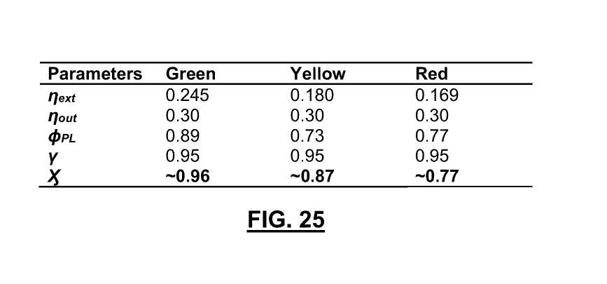

Using Equation (1a) and device parameters from optimized single emitter devices illustrated in FIG. 20, the fraction of emissive excitons trapped by each emitter, [symbol] , can be derived to be ˜0.96, ˜0.87, and ˜0.77 for green, yellow and red devices, respectively, as listed in FIG. 25.

Since the green emitter exhibits the highest exciton trapping capability in the device, it will be beneficial to incorporate it as co-doped EMLs to compensate for the relatively inferior trapping ability of yellow and red emitters and hence increase the utilization rate of the available excitons.

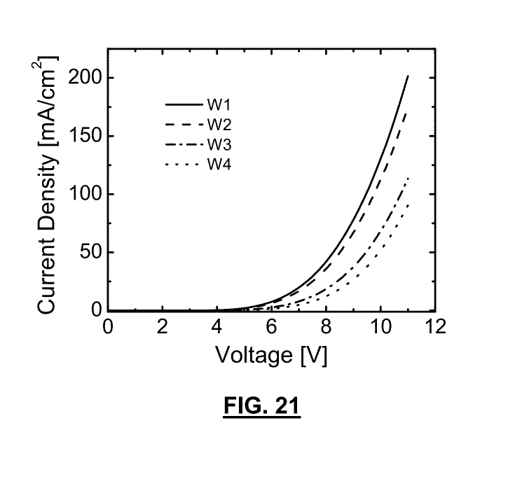

This is also reflected from the current density versus voltage (J-V) plot of the WOLED devices as shown in FIG. 21, where a reduction in current density is observed with the incorporation of the green emitter. This may be attributed to increased hole trapping by the green emitter, which leads to direct exciton formation and effective widening of the recombination zone, followed by efficient exciton energy transfer to the red and yellow emitters.

According to Equation (1b), it can be seen that the presence of [symbol] _{D} together with a high η_{D-A} results in an enhanced emission from the lower energy emitter. However, if η_{D-A} is not sufficiently high, the [symbol] _{D} may also contribute to green (donor) emission (˜520 nm) as shown in FIG. 15. In terms of our WOLED design, the green donor emission will nevertheless contribute favorably to overall device efficiency of W2 to W4.

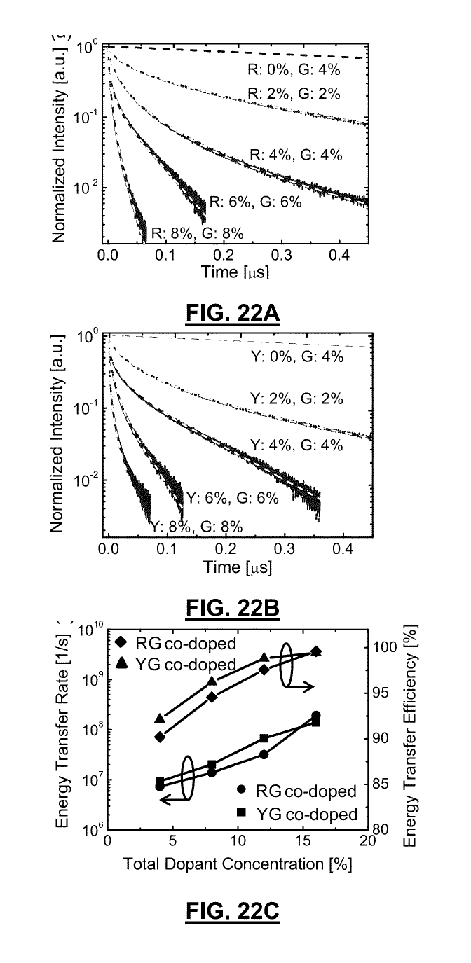

In order to determine η_{D-A}, time-correlated single photon counting (TCSPC) technique has been conducted to measure the transient decay time of the donor emission at 520 nm under various co-doping concentrations for both red and yellow doped CBP films as shown in FIG. 22. Control samples of green donor-doped only films at various concentrations (2%, 4%, 6%, and 8%) revealed similar decay time constants of 1.15˜1.20 μs, which include both the non-radiative and radiative relaxation processes of the green donor triplet states. The dashed lines are the exponential fits to the transient decay responses. The excitation wavelength is at 350 nm. Triangles (squares) and rhombuses (circles) denote the energy transfer efficiency (energy transfer rate) of co-doped yellow and red emissive films, respectively. In co-doped films, it is anticipated that any energy transfer from the green donor to either red or yellow acceptor molecules will induce an additional green donor triplet relaxation path, leading to a shorter decay time.

The transient donor emission intensity can be expressed by:

I(t)=e^{-K}^{_{c}}^{t}(C₁+C₂e^{-k}^{ₑₜ}^{t}), (2)

where K_{c} represents the decay rate constant of the donor emission (from the control samples), kₑₜ denotes the energy transfer rate from donor to acceptor, and C₁ and C₂ are related to the donor and acceptor concentrations, respectively.

It is also noted that for high co-doping concentrations, an extra exponential term is included to account for donor-to-donor exciton diffusion before eventually transferring to an acceptor, which is a relatively slower process. In this case, equation (2) is modified as follows:

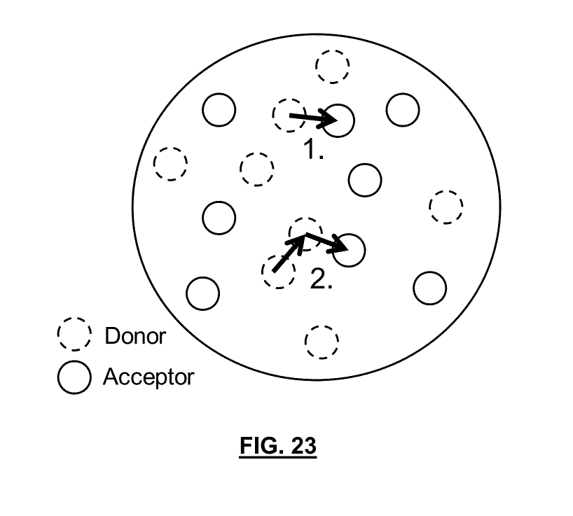

I(t)=e^{-K}^{_{c}}^{t}(C₁+C₂e^{-k}^{ₑₜ}^{t}+C₃e^{-K}^{ₑₜ}^{t}), (3)

where [symbol] ₑₜ is the relatively lower energy transfer rate ascribed to the donor-to-donor energy transfer or exciton diffusion processes taking place prior to the eventual donor-to-accepter energy transfer as illustrated in FIG. 23 (process 2). C₃ is related to both donor and acceptor concentrations. In this case, the energy transfer rate is taken as the average of kₑₜ and [symbol] ₑₜ.

Using Equations (2) and (3), the transient response of the donor emission in co-doped films can be expressed as shown in FIGS. 22a and 22b, and obtain the energy transfer rate as shown in FIG. 13c. The energy transfer efficiency can then be expressed as:

$${η}_{D - A} = \frac{{k}_{et}}{{k}_{et} + {k}_{r} + {k}_{nr}} = \frac{{k}_{et}}{{k}_{et} + {K}_{c}} . \qquad ( 4 )$$

From FIGS. 22a and 22b, it is observed for both red and yellow emissive films a faster transient decay with increasing co-doping concentration, which corresponds to a reduction in donor-to-acceptor molecule distance that promotes the energy transfer process.

It is worth noting that in co-doped films, the transient decay response of the lower energy red and yellow emissions does not alter significantly compared to those from single doped red and yellow films, suggesting no other non-radiative energy transfer path took place. This is expected since any increase in the excited state population of the lower energy emitters should not affect their triplet radiative decay lifetimes.

As shown in FIG. 22c, the η_{D-A}, is calculated to be as high as ˜90.2 and ˜92.1% for red and yellow emissive films, respectively, at low co-doping concentrations (2% each). The η_{D-A} further reaches ˜99.6% and ˜99.4% for red and yellow emissive films, respectively, at high co-doping concentrations (8% each), which represents nearly perfect energy transfer.

This high energy transfer efficiency together with an increased exciton utilization rate can well-explain the observed spectral EL intensity enhancement of the lower energy red and yellow emissions, and hence the overall device efficiency improvement of white OLEDs W2 to W4.

### EXPERIMENTAL

The following examples are provided for a further understanding of the invention.

### Example W1

### Comparative

An ITO coated glass substrate was ultrasonically cleaned with a standard regiment of Alconox™ dissolved in deionized (DI) water, DI water, acetone, and methanol. The ITO substrates were then treated using UV ozone treatment for 10 minutes in a PL16-110 Photo Surface Processing Chamber (Sen Lights).

All subsequent organic layers are deposited by thermal evaporation under ultra-high base vacuum (˜10⁻⁸ torr) using a Kurt J. Lesker LUMINOS® cluster tool.

A 1 nm thick layer of MoO₃ is deposited.

A 35 nm thick layer of CBP is deposited.

A 17 nm thick layer of CBP doped with red emitter Ir(MDQ)₂(acac) in 8 wt % of CBP is deposited.

A 3.5 nm thick layer of CBP doped with yellow emitter Ir(BT)₂(acac) in 8 wt % of CBP is deposited.

A 3 nm thick layer of CBP doped with green emitter Ir(ppy)₂(acac) in 8 wt % of CBP is deposited.

A 10 nm thick layer of CBP doped with blue emitter Flrpic in 20 wt % of CBP is deposited.

A 55 nm thick layer of TPBi is deposited.

A 1 nm thick layer of LiF is deposited.

A 100 nm thick layer of Al is deposited.

### Example W2

### Comparative

An ITO coated glass substrate was ultrasonically cleaned with a standard regiment of Alconox™ dissolved in deionized (DI) water, DI water, acetone, and methanol. The ITO substrates were then treated using UV ozone treatment for 3 minutes in a PL16-110 Photo Surface Processing Chamber.

All subsequent organic layers are deposited by thermal evaporation under ultra-high base vacuum (˜10⁻⁸ torr) using a Kurt J. Lesker LUMINOS® cluster tool.

A 1 nm thick layer of MoO₃ is deposited.

A 35 nm thick layer of CBP is deposited.

A 17 nm thick layer of CBP doped with red emitter Ir(MDQ)₂(acac) in 8 wt % of CBP is deposited.

A 3.5 nm thick layer of CBP doped with both yellow emitter Ir(BT)₂(acac) in 8 wt % of CBP and green emitter Ir(ppy)₂(acac) in 8 wt % of CBP is deposited.

A 3 nm thick layer of CBP doped with green emitter Ir(ppy)₂(acac) in 8 wt % of CBP is deposited.

A 10 nm thick layer of CBP doped with blue emitter Flrpic in 20 wt % of CBP is deposited.

A 55 nm thick layer of TPBi is deposited.

A 1 nm thick layer of LiF is deposited.

A 100 nm thick layer of Al is deposited.

### Example W3

### Inventive

An ITO coated glass substrate was ultrasonically cleaned with a standard regiment of Alconox™ dissolved in deionized (DI) water, DI water, acetone, and methanol. The ITO substrates were then treated using UV ozone treatment for 3 minutes in a PL16-110 Photo Surface Processing Chamber.

All subsequent organic layers are deposited by thermal evaporation under ultra-high base vacuum (˜10⁻⁸ torr) using a Kurt J. Lesker LUMINOS® cluster tool.

A 1 nm thick layer of MoO₃ is deposited.

A 35 nm thick layer of CBP is deposited.

A 17 nm thick layer of CBP doped with both red emitter Ir(MDQ)₂(acac) in 8 wt % of CBP and green emitter Ir(ppy)₂(acac) in 8 wt % of CBP is deposited.

A 3.5 nm thick layer of CBP doped with both yellow emitter Ir(BT)₂(acac) in 8 wt % of CBP and green emitter Ir(ppy)₂(acac) in 8 wt % of CBP is deposited.

A 3 nm thick layer of CBP doped with green emitter Ir(ppy)₂(acac) in 8 wt % of CBP is deposited.

A 10 nm thick layer of CBP doped with blue emitter Flrpic in 20 wt % of CBP is deposited.

A 55 nm thick layer of TPBi is deposited.

A 1 nm thick layer of LiF is deposited.

A 100 nm thick layer of Al is deposited.

### Example W4

### Inventive

An ITO coated glass substrate was ultrasonically cleaned with a standard regiment of Alconox™ dissolved in deionized (DI) water, DI water, acetone, and methanol. The ITO substrates were then treated using UV ozone treatment for 3 minutes in a PL16-110 Photo Surface Processing Chamber.

All subsequent organic layers are deposited by thermal evaporation under ultra-high base vacuum (˜10⁻⁸ torr) using a Kurt J. Lesker LUMINOS® cluster tool.

A 1 nm thick layer of MoO₃ is deposited.

A 35 nm thick layer of CBP is deposited.

A 17 nm thick layer of CBP doped with both red emitter Ir(MDQ)₂(acac) in 4 wt % of CBP and green emitter Ir(ppy)₂(acac) in 4 wt % of CBP is deposited.

A 3.5 nm thick layer of CBP doped with both yellow emitter Ir(BT)₂(acac) in 4 wt % of CBP and green emitter Ir(ppy)₂(acac) in 4 wt % of CBP is deposited.

A 3 nm thick layer of CBP doped with green emitter Ir(ppy)₂(acac) in 8 wt % of CBP is deposited.

A 10 nm thick layer of CBP doped with blue emitter Flrpic in 20 wt % of CBP is deposited.

A 55 nm thick layer of TPBi is deposited.

A 1 nm thick layer of LiF is deposited.

A 100 nm thick layer of Al is deposited.

It is anticipated that the CRI could further be improved with the use of higher efficiency deep blue emitters, which are mostly proprietary.

It is also anticipated that this TEC concept does not require the use of exotic ultra-wide energy gap and associated ultra-high triplet energy host materials for the blue emitter, which is commonly believed to be a prerequisite for high efficiency white OLEDs.

It is also anticipated that the TEC concept could further spur the development of a new generation of low-cost white OLEDs by enabling the use of alternative, more abundant metal-organic complexes such as Pt- or even Cu-based emitters as low energy acceptor phosphors, provided the energy transfer process remains in effect.

What is claimed is:

1. An organic light-emitting device, comprising an anode, a cathode, at least two light-emitting layers located between the anode and the cathode, at least one light-emitting layer comprising:
a host compound comprising:
a first compound capable of phosphorescent emission at room temperature; and
a second compound capable of phosphorescent emission at room temperature that has a peak emission wavelength at least 10 nm higher than the first compound;

2. The organic light-emitting device of claim 1, wherein the device has an external quantum efficiency greater than that of a second device, wherein the second device differs from the first device only in that the second device has a light-emitting layer that does not contain the first compound.

3. The organic light-emitting device of claim 1, comprising 5 light-emitting layers, each of the light-emitting layers emitting at a distinct wavelength peak emission wavelength.

4. The organic light-emitting device of claim 1, comprising 4 light-emitting layers, each of the light-emitting layers emitting at a distinct wavelength peak emission wavelength.

5. The organic light-emitting device of claim 1, comprising 3 light-emitting layers, each of the light-emitting layers emitting at a distinct wavelength peak emission wavelength.

6. The organic light-emitting device of claim 1, with a total of 2 light-emitting layers wherein each of the light-emitting layers has a different color of emission.

7. The organic light-emitting device of any one of claims 1-6, wherein the light-emitting layers are ordered from high to low triplet energy, with respect to the cathode.

8. The organic light-emitting device of claims 1-6, wherein the light-emitting layers are configured without a spacer between at least one of the light-emitting layers.

9. The organic light-emitting device of claim 8, wherein the light-emitting layers are configured without a spacer between any of the light-emitting layers.

10. The organic light-emitting device of claim 1, wherein at least one of the first and second compounds is an organometallic compound.

11. A process for making the organic light-emitting device of claim 1, comprising solution depositing the light-emitting layers.

12. A process for making the organic light-emitting device of claim 1, comprising vapor depositing the light-emitting layers.

13. A method of producing an organic light-emitting device that comprises an anode, a cathode, at least two light-emitting layers located between the anode and the cathode, and at least one light-emitting layer comprising:
Sandwiching between the anode and cathode a first light emitting layer and a second light emitting layer, the second light emitting layer comprising a host compound having distributed therein:
a first compound capable of phosphorescent emission at room temperature; and
a second compound capable of phosphorescent emission at room temperature that has a peak emission wavelength at least 10 nm higher than the first compound.
